(19) United States
(12) Patent Application Publication
(10) Pub. No.: US 2014/0203836 A1
(43) Pub. Date: Jul. 24, 2014

(54) METHOD OF CHARACTERIZING THE SENSITIVITY OF AN ELECTRONIC COMPONENT SUBJECTED TO IRRADIATION CONDITIONS

(71) Applicants: Florent Miller, Levallois (FR); Cecile Weulersse, Versailles (FR)

(72) Inventors: Florent Miller, Levallois (FR); Cecile Weulersse, Versailles (FR)

(73) Assignee: EUROPEAN AERONAUTIC DEFENCE AND SPACE COMPANY EADS FRANCE, Paris (FR)

(21) Appl. No.: 14/342,998

(22) PCT Filed: Sep. 5, 2012
(86) PCT No.: PCT/EP2012/067305

§ 371 Date: Mar. 28, 2014

(30) Foreign Application Priority Data
Sep. 6, 2011 (FR) 1157892

(51) Int. Cl. G01R 31/26

(52) U.S. Cl. CPC G01R 31/2601
USPC 324/762.01

(57) ABSTRACT

A method of selecting a piece of electronic equipment subjected to irradiation conditions comprising at least one electronic component by characterizing a sensitivity parameter of the electronic component to the irradiation conditions listed in a predetermined specifications. The electronic component is irradiated with a source of ionizing radiation having the known irradiation characteristics and geometry. A set of operating values of the electronic component are measured during the irradiation of the electronic component. The sensitivity of the electronic component are measured for a number of irradiation conditions lower than all of the conditions listed in the specifications. The measured results are extrapolated to the other irradiation conditions of the specifications.

The present invention relates to the field of devices and methods for controlling the quality of electronics. It in particular relates to a method for characterizing the sensitivity of a component or a piece of electronic equipment subjected to ionizing radiation such as that present in the natural radiation environment. The invention employs an ionizing radiation source and a predicting tool.

### INTRODUCTION AND PRIOR ART

Electronic components, especially complex components and power components, are more and more commonly used in hostile environments, and in particular in environments that subject them to various stresses (due to cosmic radiation, electromagnetic radiation, etc.), especially when used on-board aircraft or satellites. It is therefore desirable to know, for the sake of operational safety, their sensitivity to these stresses, this sensitivity then being defined as the probability of a single error, simultaneous errors, or even destructive failure occurring. These errors may cause an application executed by the component to malfunction.

One of the aims of the invention is to determine the sensitivity of electronic components and systems to ionizing radiation, in other words particles such as heavy ions, neutrons, protons or any other particles leading to the generation of charge via direct or indirect interaction in the electronic components.

The operation of electronic components may be stressed by the environment, for example the natural or artificial radiation environment or the electromagnetic environment, in which they operate. In the case of radiation environments (neutrons, protons, ions, X-ray flashes, gamma rays, muons, etc.), these stresses are due to interactions between the material of the component and ionizing particles. One of the consequences of these stresses is the creation of parasitic currents in the component.

Depending on the location of the interactions between the material of the component and the incident particles, and depending on the operating conditions of the component, these interactions may have various effects, and may lead the device, and the application using it, to malfunction temporarily or permanently. These types of failure are grouped under the term single effects.

Heavy-ion and proton strikes are typically encountered in space by satellites and launch vehicles. At the lower altitudes at which aircraft operate, low-energy proton and neutron strikes are above all observed. Neutrons are also responsible for malfunctions at ground level, such as, for example, in the electronics of hand-held devices and servers.

Particle-accelerator testing is the tool of reference for characterizing the sensitivity of electronic components to particles from the natural radiation environment. However, this type of test is very expensive because exhaustive characterization requires substantial beam time.

Moreover, the availability of most of these machines is relatively limited because they are few in number and subject to very high demand.

### SUMMARY OF THE INVENTION

Therefore, the invention relates to a method for selecting a piece of electronic equipment comprising at least one electronic component, said piece of electronic equipment potentially being subjected to the radiation conditions listed in a preset set of specifications.

The method comprises a phase of characterizing a sensitivity parameter of the component to these radiation conditions.

This phase comprises:
a step of irradiating the component with an ionizing radiation source having known properties and irradiation geometry; and
a step of measuring a set of operating values (experimental points of characterization) of the electronic component during this irradiating step.

In the present example implementation,
the irradiating step comprises measuring the sensitivity of the component for a number of radiation conditions smaller than the set of conditions listed in the specifications; and
the method furthermore comprises a step of extrapolating, using a simulating code, the measurement results to the other radiation conditions in the specifications.

It will be understood that the ionizing radiation source allows the sensitivity of the component to be characterized under only a small number of radiation conditions (especially a small number of incident-particle energies).

The simulating code then uses this characterization, performed under a small number of radiation conditions, to calculate the sensitivity of the component under a much larger number of radiation conditions.

Therefore, here a characterization of the sensitivity of a component is obtained at lower cost and with a piece of equipment that is very simple in comparison to a particle accelerator.

The ionizing radiation sources envisageable for the invention are preferably inexpensive and compact.

In a first embodiment, the method uses a radioactive-isotope-based source that permanently emits ionizing radiation, such as americium sources that generate alpha particles or californium sources that produce ions in an energy range between 0 and 15 MeV with an average energy of 2.4 MeV.

Alternatively, and preferably, the method uses a small electric generator that emits ionizing radiation temporarily (for example only when a voltage is applied in order to accelerate projectile particles).

More particularly, the method uses a source of monoenergetic neutrons generated by the fusion of two atoms.

In one advantageous embodiment, this is a D-D reaction (involving the fusion of two deuterium atoms, producing 2.5 MeV neutrons) or, preferably, a D-T neutron source (fusion of a deuterium atom with a tritium atom, producing 14.1 MeV neutrons). This type of ionizing radiation source is relatively common, quite inexpensive, small in size (typically a few tens of centimeters in length) and therefore allows sensitivity to be characterized with ease in a particular radiation range.

The choice of D-T or D-D sources is particularly advantageous in that the energy of the emitted neutrons is perfectly known.

The operating principle of these various sources of radiation is known per se and, therefore, is not described in more detail here.

Nevertheless, characterization of the sensitivity of a component to ionizing radiation with such a source is not exhaustive, because these types of source emit particles the properties, especially energies, of which are restricted to a very narrow range. In the example of D-T neutron tubes, only neutrons with an energy of 14.1 MeV are emitted.

Characterization can only be said to be exhaustive if it is carried out under a sufficient number of energy conditions (typically between 5 and 10) and over an energy range representative of the radiation environment that the component or electronic system will see. The list of energy conditions corresponding to the specifications of a component naturally depends on the application for which this component is intended.

Usually, a particle accelerator test using neutrons involves measurements carried out for various energies between 1 MeV and 150 MeV, such as, for example, at 10 MeV, 30 MeV, 60 MeV, 100 MeV and 150 MeV.

In the case of energies higher than 15 MeV, the neutrons are either produced in nuclear fission reactors or particle accelerators in which accelerated protons are made to collide with a target material in order to create secondary neutrons. These neutrons have a spectrum in which 50% of the neutrons created are monoenergetic and the remaining 50% have lower energies. These two methods for generating neutrons require extremely complex machines that are therefore rare and very expensive to access.

Consequently, carrying out exhaustive characterizations of the sensitivity of electronic components to radiation may prove to be very expensive and require planning far in advance of the irradiation campaign.

To increase flexibility and greatly reduce the cost of this characterization, the present method for characterizing the sensitivity of a component to radiation combines experimental characterization using an ionizing radiation source having limited properties (especially regarding energy range) with a simulating code.

An additional advantage of this type of ionizing radiation source is that its properties and geometric radiation configuration (energy spectrum, flux, etc.) are perfectly known and therefore easily modeled with a simulating tool.

As regards the simulating code used to calculate the sensitivity of a component under a number of radiation conditions, it requires a limited number of input parameters to calculate, for a radiation environment, the probability that radiation-related effects (typically a failure of preset type) will occur. It may either be an analytical method (such as, for example, a BGR, SIMPA or PROFIT method) or a Monte-Carlo type approach. In order to predict the sensitivity of a component to radiation, Monte-Carlo approaches simulate a large number of incident particles and study the response of the component to each event individually. This type of approach allows statistical data to be gathered and an average response to be obtained for the component.

These input parameters are related to the component studied and to the type of single effect. They especially comprise, in the case of upset of a logic cell: 1/ the notion of critical charge, which is the charge deposition required to provoke the radiation event of interest (for example a change of logic state in an elementary cell of a memory or processor component) or, equivalently, a criterion of maximum current over a maximum time, and on the definition 2/ of the size of the sensitive region (also called the sensitive volume) associated with an elementary cell of the component, 3/ of the distance to the closest neighboring elementary cells, and 4/ the logic organisation of the memory, namely whether 2 bits of a given word are physically adjacent or not.

The radiation events of interest (called single events) are varied: it may be a question of the change of logic state of a cell or of a plurality of cells of a memory or processor component (called a single event upset (SEU) and a multiple cell upset (MCU), respectively), an error capable of modifying the overall operation of a component (called a single event functional interrupt (SEFI)), a short circuit (single event latchup), a transient effect (single event transient), destructive mechanisms in a power component (called single event burnout (SEB) or single event latchup (SEL)) or any other single effect related to the interaction of a particle of the radiation environment with an electronic component.

The input parameters of the simulating code, which parameters are associated with a component or piece of electronic equipment, may be obtained in various ways. Typical values associated with a component of a known technological step (“technological node”) may be estimated using values listed in technological roadmaps (especially the International Technology Roadmap for Semiconductors (ITRS)). Such technological roadmaps are for example provided by manufacturers, with typical values associated with the arrival dates of future products in their ranges.

Alternatively, parameters related to the topology of the components may also be determined via a technological analysis of the component, or during laser mapping associated with the type of failure studied. Specifically, a laser may be used to simulate the same types of error as those triggered by particles from the natural radiation environment. During laser mapping, the position of the laser on the component is perfectly controlled, it is therefore possible to map the position of sensitive regions associated with the various types of errors.

The prerequisite is for a testing system to be used to detect, consecutively to the laser blasts, the triggering of these errors. In this respect, laser mapping is associated with the type of failure that may be detected by the testing system. The method for carrying out such laser mapping is known per se and as such departs from the scope of the invention. Therefore, it is not described in more detail here.

In the present example implementation of the method, at least certain of these input parameters of the simulating code are determined on the basis of experimental points of characterization obtained in the step with the ionizing radiation source having limited properties.

By comparing the experimental characterization of the sensitivity of the component, which characterization is obtained by virtue of the ionizing radiation source the properties of which are limited to certain types of radiation and certain energy values, with a prediction obtained, under the same conditions, by virtue of the simulating code, it is possible to refine the input parameters of the simulating code so as to obtain a more precise prediction of the sensitivity of the component under other radiation conditions.

One significant advantage, relative to the use of a simulating code alone to predict the sensitivity of the component, is that here this code is refined on the basis of experimental tests carried out on the component itself, and therefore this refinement takes into account and is extrapolated from defects specific to the component.

According to an advantageous method of implementation, the step of determining certain input parameters of the simulating code comprises a phase of determining whether a radiation event takes place following the passage of a particle, such as simulated by the predicting code, this phase employing an approach based on whether the threshold values relating to the one or more criteria used by the simulating code to model the radiation event of interest are reached for the geometric configuration relating to the sensitive regions associated with this criterion.

In a particular case, this approach may be based either on evaluation of the charge deposited by the ion in the sensitive volume of the elementary cell and comparison of said charge to the critical charge, which represents an upset threshold value, or on evaluation of the shape of the current generated, as a function of time, by the passage of the ion through the sensitive volume of the elementary cell and comparison of said shape with the criterion of maximum current over a maximum time (imax, timax), which represents the upset threshold.

Advantageously, the step of determining certain input parameters of the simulating code comprises an optimizing phase for determining a most probable set of parameters allowing the measurement results obtained experimentally, in the step of measuring the reaction of the component to radiation, using the ionizing radiation source having limited properties, to be reproduced using the simulating code.

More particularly, in this case, the set of parameters employed in the optimizing phase comprises a threshold value or a plurality of threshold values relating to the one or more criteria used by the simulating code to model the radiation event of interest, and the items of geometric information relating to the sensitive regions associated with this criterion.

In one embodiment, the set of parameters comprises the size of the sensitive volume, the positions of the sensitive volumes and the critical charge or the pair of parameters (maximum current, maximum time).

Advantageously, for components comprising memory cells for which the radiation event of interest is a change of logic state of a cell or of a plurality of cells, the set of parameters comprises the critical charge, defined as the charge deposition required to provoke a radiation event of interest, or equivalently, a criterion of maximum current over a maximum time (imax, timax), and on the size of the sensitive region associated with this criterion, and, optionally, the distance to the closest neighboring cells, and the logical organization of the memory, namely whether 2 bits of a given word are physically adjacent or not.

In one particular embodiment, on the basis of the set of determined parameters, the simulating code is used to calculate the expected sensitivity for new radiation configurations meeting the specifications.

### DESCRIPTION OF THE DRAWINGS

Features and advantages of the invention will be better appreciated by virtue of the following description, which description describes the features of the invention by way of a nonlimiting example of an application.

The description refers to the appended figures, in which:

FIG. 1 is a schematic illustrating the various elements employed in the method;

FIG. 2 is a flow diagram of the steps of an example embodiment of the method according to the invention;

FIG. 3 illustrates the general principle of a Monte-Carlo code for predicting the sensitivity of electronic components, used in the present example implementation of the method;

FIG. 4 symbolically depicts the database of nuclear reactions used in a Monte-Carlo simulating code; and

FIG. 5 illustrates the principle behind the two upset criteria.

### DETAILED DESCRIPTION OF AN EMBODIMENT OF THE INVENTION

In the rest of the description the particular case of an electronic memory component, comprising an array of elementary cells capable of adopting a plurality of logic states depending on their electronic charge, will be considered. However, the method described here more generally applies to any type of component or piece of electronic equipment.

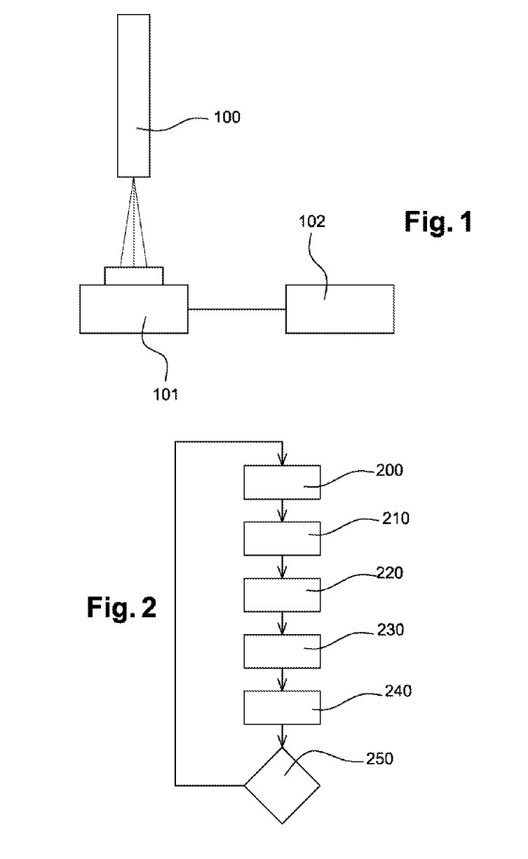

The method for selecting electronic components depending on their sensitivity to ionizing radiation implements various elements that are illustrated in FIG. 1.

Firstly, a radioactive source 100 of a type known per se is used, said source 100 being installed on a supporting structure (not shown in the figure) that is intended to receive a piece of electronic equipment or a component 101 placed a distance h from the source and according to a preset geometry.

The method also employs means 102 for measuring various signals of interest that originate from the component 101 when the latter is irradiated by the source 100. These measuring and calculating means 102 take, in the present completely nonlimiting implementation of the method, the form of a PC microcomputer, known per se, equipped with conventional user interfaces and memory storage means.

A software package for predicting the sensitivity of a component to ionizing radiation is installed on this microcomputer.

The method, such as described here, comprises a series of steps, a flow diagram of which is illustrated in FIG. 2.

In a first step 200, an electronic component 101 to be analyzed is placed under the ionizing radiation source 100, under preset geometric conditions. This ionizing radiation source 100 is, in the present example, a D-T source, i.e. its operating principle is based on fusion of a deuterium atom and a tritium atom, thus producing 14.1 MeV neutrons on demand. The radiation properties of this ionizing radiation source 100 are limited to one type of particle (neutrons) and a single energy: 14.1 MeV; but in contrast it is perfectly known.

As a variant, this source 100 is a D-D source, or alternatively a permanent radioactive source such as an americium source, which generates alpha particles, or a californium source, which produces neutrons in an energy range between 0 and 15 MeV with an average energy of 2.4 MeV.

In the implementation described here, the distance h between the ionizing radiation source 100 and the electronic component 101 is known with precision, allowing the flux of radiation received by the component to be estimated with precision. The geometric configuration of the irradiation is perfectly known (distance between the piece of equipment or component to be tested and the source, solid angle if the source is isotropic, etc.).

It is therefore possible to know, with precision, the characteristics and the flux of the particles that are generated by the radiation source and that strike the electronic component 101 to be tested.

Next, in a step 210, the component 101 is subjected to irradiation by the ionizing radiation source 100. A modification of state or of operation of the component or of certain parts results.

In a step 220, a series of measurements of the reaction of the component to this radiation are carried out.

Signals of interest are solicited from the component to be tested or the piece of equipment, or observed, before and/or during and/or after the irradiation, in order to allow sensitivity to radiation, in the given irradiation configuration, to be evaluated.

The signals of interest are, for example, in the case of memory components, the content of items of logic information contained in each memory cell. If one or more cells have seen their content change from 1 to 0 or from 0 to 1, this indicates a level of sensitivity of the component to the particles (which is equivalent to a probability of this type of error occurring). In a power MOS component, it is possible to observe variations in the drain voltage; if, during an impact, the latter passes to 0 V, this indicates a short-circuit type failure (called an SEB) related to the passage and to the interaction of a particle. They are logic and/or electrical signals.

The signals of interest may, for example, be observed by a dedicated test card. In the case of memories, it may be a question of the logic content of each of the memory cells of the component, the test card generating signals (especially addressing signals) that allow the content of each of the memory cells of the component to be read. Such systems are well known in the art.

In a following step 230, a set of parameters for input into a pre-chosen simulating code are determined, it being understood that some of these parameters may optionally be obtained from the literature and/or by other experimental means, this set of input parameters best allowing the results of the measurements of the reaction of the component to this radiation to be reproduced by calculation.

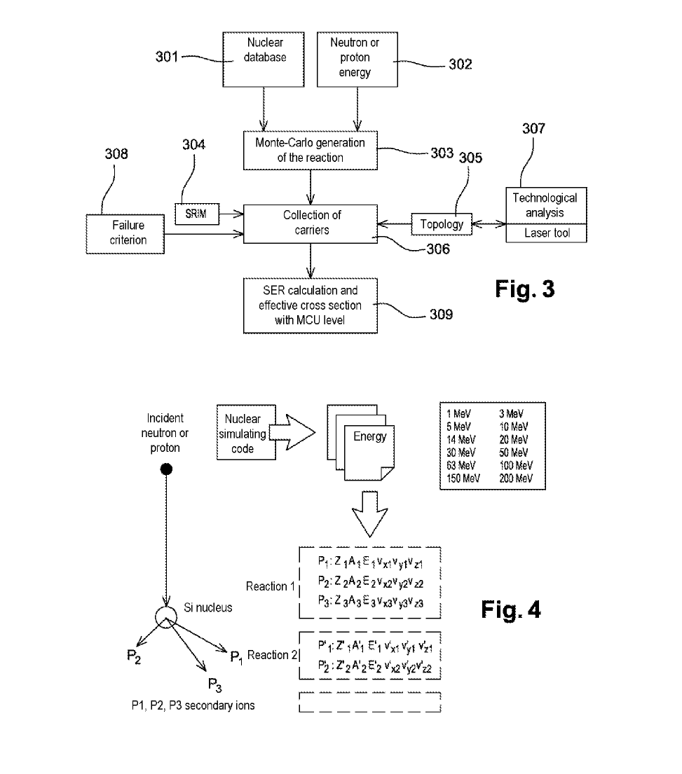

With the aim of evaluating the sensitivity of the given electronic component 101 in a given radiation environment (space, avionic or atmospheric environment), the step 230 of determining input parameters (and the step 240 of extrapolating to other ionizing radiation conditions) uses an analytical method or a Monte-Carlo analysis to predict the sensitivity of the electronic component. The rest of the description describes a Monte-Carlo analysis procedure (see FIG. 3) but simpler analytical procedures may also perfectly well be used.

Here, it will be recalled that such Monte-Carlo calculation tools are based on producing by sampling 303 (in the statistical sense of the word) a large number of simulations reproducing the conditions of possible ionizing traces resulting from nuclear reactions.

The Monte-Carlo calculation tool has access to a database of nuclear interactions 301 characterizing the reaction products obtained when an incident particle collides with a target atom.

The calculation procedure used in the present example implementation of the method consists in creating a set of randomly sampled 303 nuclear reactions 302 associated with sampled locations.

For each of these configurations (nuclear reaction, location) an analysis, based on a simplified model of the physical mechanisms at play, makes it possible to decide whether an error in the operation of the component (for example a change in logic state of an elementary cell or the triggering of a destructive effect in a power component inter alia) induced by secondary ions having certain properties, has occurred.

Such a simulator either allows error rate (SER) in a given radiation environment, or effective cross section, which is a measure of the sensitivity of a component as a function of particle energy or particle energy loss per unit length, to be calculated (step 309, FIG. 3).

Monte-Carlo predicting codes allow a large number of elementary cells and the geometry of the component to be taken into account.

Therefore, they allow the problem of multiple effects (including MCU multiple upsets) i.e. effects that appear simultaneously in various cells of the component, to be treated.

These multiple events are considered, at the present time, to be a major problem because their incidence has multiplied due to decreases in transistor size. In addition, it is much harder to detect and correct these multiple errors by means of an error detection and correction system. Specifically, parity checking allows single events to be detected, but if two events occur simultaneously within the same word, parity checking will not detect them. In order to detect multiple events it is necessary to use more resource-intensive error detection/correction codes such as Hamming code (correction of one error/detection of two errors) or Reed Salomon code.

The simulating tool used in the present method allows three problems to be solved:
1—the Monte-Carlo sampling can be made specific to the radiation environment in question (this is the Monte-Carlo sampling of the products of neutron/silicon or proton/silicon nuclear reactions);
2—it allows the properties of ionizing products (by virtue of a database of nuclear interactions) and ionization of the material to be taken into account in the physics of the nuclear interaction; and
3—it allows an error criterion, namely the danger that secondary ions pose to the component, to be determined.

In order to study single effects (defined as temporary or permanent malfunctions in the component due to interactions between the material of the component and incident particles under the operating conditions of the component) induced in electronic components by atmospheric neutrons or by protons from the radiation belt, it is necessary to know the ionizing products (also called secondary ions) that these nucleons produce when they interact with atoms of the target.

On account of the energy window (from 1 MeV to 1 GeV) of the various types of interaction, various models are used to generate nuclear databases allowing the specifics of the various interaction mechanisms to be described, i.e. the types of reaction and their energies.

Dedicated calculation codes, such as those known by the names HETC, MC-RED, GEANT4 or MCNP—registered trademarks—(dependent on the energy of the incident particle) or evaluated nuclear data such as ENDF or JENDL—registered trademarks—may be used.

Use of these codes has allowed databases of recommended nuclear data, which are not recalculated each time the invention is used, to be obtained. In fact, new databases are generated only when it is necessary to take into account the use, in the semiconductors, of new materials. In the context of the invention databases are considered to already have been generated for the materials of interest (silicon, SiO₂, tungsten, SiC, GaN, etc.).

The databases of nuclear interactions employed cover neutrons and protons and are, for each incident energy, made up of hundreds of thousands of inelastic and elastic nuclear events with details of the nuclear reactions, i.e. the atomic number and the atomic mass of the secondary ions, their energies and their emission characteristics (angles of emission), being given.

In elastic nuclear reactions, the nature of the particles involved in the interaction does not change and total kinetic energy is conserved.

Inelastic reactions are varied, each reaction being characterized by an energy threshold. These reactions induce the generation of one or more secondary ions.

The simplified model of the physical mechanisms at play is obtained from the study of a large number of finite-element simulations, which are carried out using dedicated simulating tools such as the commercially available tools sold by Synopsys or SILVACO—registered trademarks. Here, the simplified model of the physical mechanisms at play is considered to have already been obtained for the failures/errors of interest. In particular, these models currently exist for SRAM memory elements and power components such as power MOSFETs and IGBTs.

These simulations allow, for a given and previously meshed (i.e. modeled with finite elements) component structure, the operating equations of the semiconductor to be solved for each mesh point of the structure, but also at each instant in the temporal domain studied.

These component simulations allow the behaviour that an electronic component will exhibit, with respect to an ionizing interaction, to be studied with great precision.

Thus, for example, it is especially known that in the case of upset of an SRAM memory cell, its sensitivity is characterized by its critical “LET parameter” (energy loss per unit length) or critical charge.

For an error to be generated, it is necessary for the ion or ions generated by the nuclear reaction to deposit sufficient energy on the drains of off-state transistors.

Component simulations have shown that conditions favoring the creation of an error are for its trace to pass near or indeed through one of the sensitive regions, in order to induce therein a parasitic current or a collection of charge sufficient to cause an upset. Simple (especially analytical) models of diffusion/collection, based on ambipolar carrier diffusion and the collection of charge on the drain of off transistors, allow the movement of carriers to be described.

Various procedures may be used to evaluate whether or not the a single effect (upset of the logic state of the cell, triggering of a destructive mechanism, triggering of a short-circuit, etc.) takes place following the passage of an ion (failure criterion 308, FIG. 3).

A first procedure takes a simplified approach (of the first order). It is based on evaluation of the charge deposited by an ion in a sensitive volume of an elementary cell, and on the comparison of the latter with the critical charge, which represents the threshold value for the upset. This is the procedure on which the simulating code used in the present method is based.

A second procedure studies the effect in more detail (second order). The collection of carriers deposited over time by the passage of an ion is studied (step 306, FIG. 3) in order to reconstruct the current produced. The variation of the current over time defines whether or not a single effect occurs.

For example, one dynamic criterion is based on the following pair: the maximum amplitude Imax of the current and the time for which this maximum current flows tImax. Since each passage of a particle induces a current of the same shape, i.e. an abrupt increase (drift mechanism) followed by a slow decrease (diffusion mechanism), each passage of an ion may be characterized by this pair. In the example of bit upsets in a memory, this criterion leads to a borderline that separates pairs (Imax, tImax) that produce upsets from pairs that do not, this borderline characterizing the sensitivity of an SRAM technology. Thus, to measure the operating defect of the component, a temporal variation in a current resulting from the excitation, a dynamic characteristic of which exceeds a threshold inducing upset of an electrical state of the component (SEU, single event upset), is measured. This procedure is used in the simulating code described here by way of completely nonlimiting example.

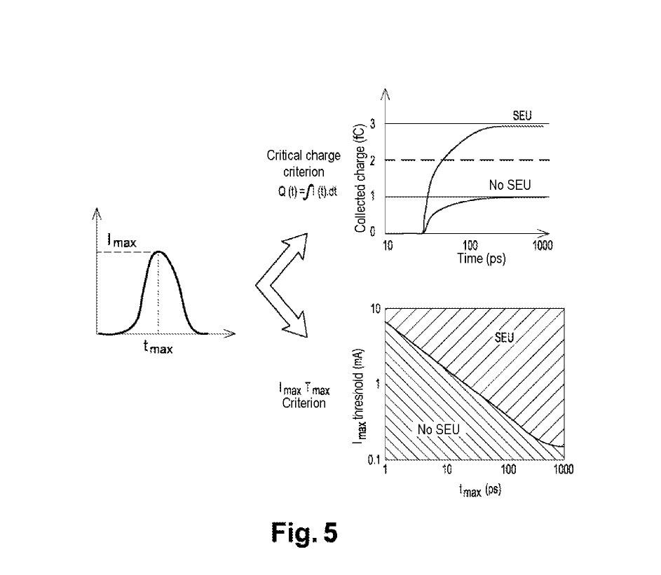

FIG. 5 illustrates the principle behind the two upset criteria.

In addition to the nuclear database 301 described above, curves are provided by a calculation code describing the behavior of the energy deposited by the ions as they pass through the material (such as the tool known by the trade mark SRIM—registered trade mark—SRIM standing for “stopping and range of ions in matter”). The nuclear databases 301 and SRIM curves 304 are fixed whatever the component and the type of error studied.

The input parameters (i.e. the numerical data characterizing the component) required to predict the sensitivity of a component, comprise, in the present example, the critical charge and items of information 305 relating to the topology of the component i.e. the volume of the sensitive regions and the distance between sensitive regions. These parameters vary depending on the component and the type of error studied.

Using the experimental points of characterization obtained with the ionizing radiation source having limited properties, an optimizing procedure, of a type known per se and hence not described here, is applied to determine the most probable set of parameters (for example the size and positions of the sensitive volumes and the critical charge) allowing the results obtained experimentally to be reproduced using the predicting code.

This procedure is simplified because the properties of the ionizing radiation source and the geometric configuration of the irradiation are perfectly known.

The evaluation of the most probable set of parameters may also be simplified if at least one of the input parameters is determined by another procedure, such as, for example, technological analysis 307 for determining the size of the sensitive regions.

This method, using an ionizing radiation source having limited properties with a predicting code, therefore makes it possible to avoid the need for expensive tests involving particle accelerators, and to characterize the sensitivity of an electronic component over a wide range of energies using, in combination, a more accessible irradiating means and a predicting code.

The predicting code is then used to determine the most probable set of parameters (especially critical charge and/or the criterion based on the pair maximum current amplitude/time for which this maximum current flows (Imax, tImax), size of the sensitive volume, and distance between neighboring sensitive volumes) in order to obtain, for the given irradiation configuration, the result that most closely reproduces the experimental characterization such as measured in step 220.

In a step 240, the simulating code thus parameterized is used to extrapolate the sensitivity of the electronic component 101 to a series of radiation conditions, given both in terms of particles and in terms of energies or deposited energy per unit length.

In a step 250, the compatibility of the electronic component 101 with a preset set of specifications is checked.

### Advantages of the Invention

This method, using an ionizing radiation source 100 having limited properties, associated with an extrapolating code, therefore makes it possible to avoid the need for expensive tests involving particle accelerators and to characterize the sensitivity of a component over a broad range of energies using, in combination, a more accessible radiation means and a predicting code.

Thus, the invention allows, for example but nonlimitingly, after the sensitivity of a component to radiation conditions has been characterized, when a dynamic application is executed on this component, it to be checked whether this component is compatible with the specifications of a piece of electronic equipment that is in the process of being designed, this piece of equipment being required to be subjected to a environment and probability of failure that are known beforehand. If, according to the characterization method, the component does not allow the specifications to be met, the designers must modify the design of the piece of electronic equipment.

1-15. (canceled)

16. A method for selecting a piece of electronic equipment comprising at least one electronic component and the electronic equipment subjectable to radiation conditions listed in a predetermined specifications, the method comprising the steps of:
characterizing a sensitivity parameter of the electronic component to the radiation conditions by:
irradiating the electronic component with an ionizing radiation source having known properties and irradiation geometry;
measuring a set of operating values or experimental points of characterization of the electronic component during the irradiating step, the sensitivity of the electronic component are measured for a subset of radiation conditions smaller than the set of conditions listed in the specifications; and
extrapolating measurement results to the other radiation conditions in the specifications.

17. The method as claimed in claim 16, the irradiating step utilizes a radioactive-isotope-based source that permanently emits ionizing radiation.

18. The method as claimed in claim 16, the irradiating step utilizes as the source an electric generator that emits ionizing radiation temporarily, the generator being a source of mono-energetic neutrons generated by a fusion of two atoms.

19. The method as claimed in claim 18, further comprising the step of generating mono-energetic neutrons of the D-T type by the electric generator by the fusion of a deuterium atom with a tritium atom.

20. The method as claimed in claim 18, further comprising the step of generating mono-energetic neutrons of the D-D type by the electric generator by the fusion of two deuterium atoms

21. The method as claimed in claim 16, further comprising the step of utilizing a simulating code requiring a limited number of input parameters related to the electronic equipment to calculate, for a radiation environment, a probability of an occurrence of a failure of a predetermined type related to the radiation.

22. The method as claimed in claim 21, wherein the input parameters related to the electronic equipment comprise: a threshold value or a plurality of threshold values relating to one or more criteria used by the simulating code to model an radiation event of interest; and geometric information relating to sensitive regions associated with said one or more criteria.

23. The method as claimed in claim 22, wherein the input parameters for components comprising memory cells, with a change of logic state of a cell or a plurality of cells as the radiation event of interest, comprise: a critical charge or a charge deposition required to provoke the radiation event of interest, or equivalently, a criterion of maximum current over a maximum time; a size of the sensitive region associated with the criterion; a distance to a closest neighboring cell, and a logic organization of the memory cells considering at least whether two bits of a given word are physically adjacent or not.

24. The method as claimed in claim 21, wherein one of the input parameters is a geometry relating to sensitive regions associated with one or more criteria used by the simulating code; and further comprising the steps of determining the geometry relating the sensitive regions by a technological analysis method or by laser mapping, and modeling a radiation event of interest based on the geometry relating to the sensitive region by the simulating code.

25. The method as claimed in 21, further comprising the step of determining certain input parameters of the simulating code based on the experimental points of characterization obtained during the measuring step with the ionizing radiation source.

26. The method as claimed in claim 25, wherein the step of determining certain input parameters further comprises a determination phase of determining whether a radiation event takes place following a passage of a particle by evaluating whether threshold values relating to one or more criteria used by the simulating code to model the radiation event of interest are reached for a geometric configuration relating to the sensitive regions associated with the criterion.

27. The method as claimed in claim 26, wherein the step of determining certain input parameters further comprises an optimization phase of determining a set of parameters to reproduce the measurement results obtained experimentally in the measuring step with the ionizing radiation source using the simulating code.

28. The method as claimed in claim 27, wherein the optimization phase employs a set of parameters comprising a threshold value or a plurality of threshold values relating to said one or more criteria used by the simulating code to model the radiation event of interest and geometric information relating to the sensitive regions associated with the criterion.

29. The method as claimed in claim 28, wherein the set of parameters for components comprising memory cells, with a change of logic state of a cell or a plurality of cells as the radiation event of interest, comprise: a critical charge or charge deposition required to provoke a radiation event of interest, or equivalently, a criterion of maximum current over a maximum time, a size of the sensitive region associated with the criterion, and, optionally, a distance to a closest neighboring cells, and a logical organization of the memory cells considering at least whether two bits of a given word are physically adjacent or not.

30. The method as claimed in claim 27, further comprising the step of calculating an expected sensitivity for new radiation configurations in compliance with the specifications utilizing the simulating code based on the set of determined parameters.
